(19) United States
(12) Patent Application Publication
(10) Pub. No.: US 2008/0139004 A1
(43) Pub. Date: Jun. 12, 2008

(54) Light emission from silicon-based nanocrystals by sequential thermal annealing approaches

(75) Inventors: Jae Hyung Yi, Cambridge, MA (US); Luca Dal Negro, Cambridge, MA (US); Lionel C. Kimerling, Concord, MA (US)

Correspondence Address: GOODWIN PROCTER LLP;PATENT ADMINISTRATOR, EXCHANGE PLACE, BOSTON, MA, 02109-2881, US

(73) Assignee: Massachusetts Institute of Technology, Cambridge, MA (US)

(21) Appl. No.: 11/637,405

(22) Filed: Dec. 12, 2006

(51) Int. Cl. H01L 21/64

(52) U.S. Cl. 438/799; 257/E21.001

(57) ABSTRACT

A method for enhancing photoluminescence includes providing a film disposed over a substrate, the film including at least one of a semiconductor and a dielectric material. A first annealing step is performed at a first temperature in a processing chamber or annealing furnace; and, thereafter, a second annealing step is performed at a second temperature in the processing chamber or annealing furnace. The second temperature is greater than the first temperature, and the photoluminescence of the film after the second annealing step is greater than the photoluminescence of the film without the first annealing step.

### GOVERNMENT LICENSE RIGHTS

This invention was made with government support under the MIT Office of Sponsored Research Project Number 6894014, sponsored by the National Science Foundation, grant number DMR-0213282. The government has certain rights to this invention.

### FIELD OF THE INVENTION

This invention pertains generally to optical materials, and in particular to light-emitting, silicon-based nanocrystals.

### BACKGROUND

Silicon (Si) has recently been shown to be a powerful material for integrated optics, modulation, switching, and even lasing. It has not, however, been proven to be an efficient light-emitting material. Light emission in bulk Si originates from a low-probability, phonon-mediated transition that unfavorably competes with fast, non-radiative recombination paths. The lack of efficient light emission in bulk Si has hampered the monolithic integration of electronic and optical devices on mass-produced Si-based chips.

Recent new techniques are providing methods to turn Si into a more efficient light-emitting material. New Si nanostructures have been synthesized that take advantage of quantum confinement to improve light-generation efficiency. Nevertheless, a need exists for further improvement.

### SUMMARY

A process is provided for improved light emission from silicon nanocrystals, a fundamental material system for CMOS-compatible light emitters. The disclosed methods may also be applied to other material systems that utilize a large number of light emitting centers of appropriate sizes. In particular, sequential thermal annealing enables the formation of a high density of silicon nanocrystals (Si-nc), favorable for better light emission and electrical injection, with CMOS-compatible matrices, e.g., Si, SiN, SiON, SiGe, etc.

In an embodiment, the invention features a method for enhancing photoluminescence, the method including providing a film over a substrate, the film including at least one of a semiconductor and a dielectric material. A first annealing step is performed at a first temperature in a processing chamber or annealing furnace. Thereafter, a second annealing step is performed at a second temperature in the processing chamber or annealing furnace. The second temperature is greater than the first temperature, and a second photoluminescence of the film after the second annealing step is greater than an initial photoluminescence of the film before the first annealing step.

One or more of the following features may be included. The substrate may remain in the processing chamber or annealing furnace between the first and second annealing steps. The substrate may be removed from the processing chamber or annealing furnace after the first step, and re-inserted into the processing chamber or furnace for the second step after a temperature of the processing chamber or annealing furnace is stabilized at the second temperature. The film may include silicon. The dielectric material may include or consist essentially of, e.g., SiO₂, Si₃N₄, Si-rich silicon oxide, Si-rich silicon nitride, and/or Si-rich oxynitride. The first temperature may be selected from a range of 300° C. to 1300° C., preferably 400° C. to 1250° C., and more preferably 500° C. to 1200° C. The film thickness may be selected from a range of 0.1 μm to 5 μm.

### BRIEF DESCRIPTION OF FIGURES

FIG. 1 is a cross-sectional view of a structure that may be employed in an embodiment of the invention;

FIGS. 2, 4a, and 4b are graphs representing annealing temperature profiles in accordance with embodiments of the invention;

FIGS. 3a, 3b, and 5 are photoluminescence spectra of materials annealed in accordance with embodiments of the invention; and

FIG. 6 is a schematic diagram illustrating an aspect of the invention.

### DETAILED DESCRIPTION

Sequential thermal annealing treatments are employed to improve the optical emission properties of Si-based materials, and to tune Si-cluster size and size distribution. As used herein, “sequential thermal annealing” refers to any combination of thermal annealing steps that includes low-temperature annealing and high-temperature annealing. “Low temperature” signifies any temperature lower than that of the main or primary annealing step.

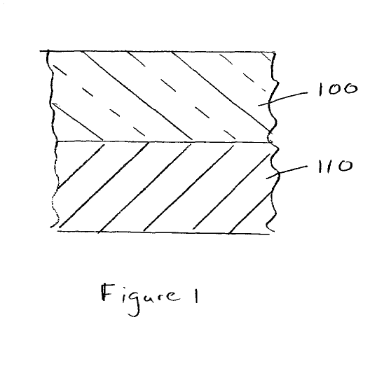

Referring to FIG. 1, a film 100 is formed over a substrate 1 10. The film 100 may include or consist essentially of a semiconductor material or a dielectric material. Examples of suitable semiconductor materials are group IV elements or compounds, such as Si, Ge, SiGe, and SiC; a III-V compound, such as GaAs, InGaAs, GaInP, GaN, InGaN, AlGaN, InP; and/or a II-VI compound, such as CdTe and ZnSe. Examples of suitable dielectric material include silicon dioxide (SiO₂), silicon nitride (Si₃N₄), Si-rich oxide (SRO), Si-rich nitride (SRN), and Si-rich oxynitride (SRON). These materials offer the advantages of efficient photoluminescence, fast recombination time, materials reliability, and the strong energy sensitization of rare earth atoms (Er in particular). Nitride and oxide materials may be doped with Er and other rare earth elements, such as Yb, Nd, Pr, Tm, Ho, etc., to extend the emission range in the near-infrared region.

The film 100 may have a thickness selected from a range of, e.g., 0.1 μm to 5 μm, e.g., 1 μm.

The film 100 may be formed by, e.g., magnetron sputtering, plasma enhanced chemical vapor deposition (PECVD), low-pressure chemical vapor deposition (LPCVD), or other suitable techniques. For example, Sio₂ may be formed by sputtering a silicon target with argon and oxygen. A silicon-rich oxide may be formed by sputtering Si and an Sio₂ targets. A silicon-rich oxide may also be grown by, e.g., PECVD or LPCVD, or may be formed by implanting Si into a Sio₂ film and annealing at a high temperature.

The substrate 110 may be a semiconductor substrate, including or consisting essentially of a group IV element or compound, such as Si, Ge, SiGe, and SiC; a III-V compound, such as GaAs, InGaAs, GaInP, GaN, InGaN, AlGaN, and InP; and/or a II-VI compound, such as CdTe and ZnSe. Examples of the semiconductor substrate include bulk Si and silicon-on-insulator (SOI).

Annealing steps following deposition cause formation of Si-nc inside the film. A high density of Si-nc, e.g., in the range of approximately 10¹⁵ to 10^{19 /cm}³, with an appropriate size, e.g., having a diameter in the range of about 1 to 10 nm, is highly preferred for good light emission from these material systems.

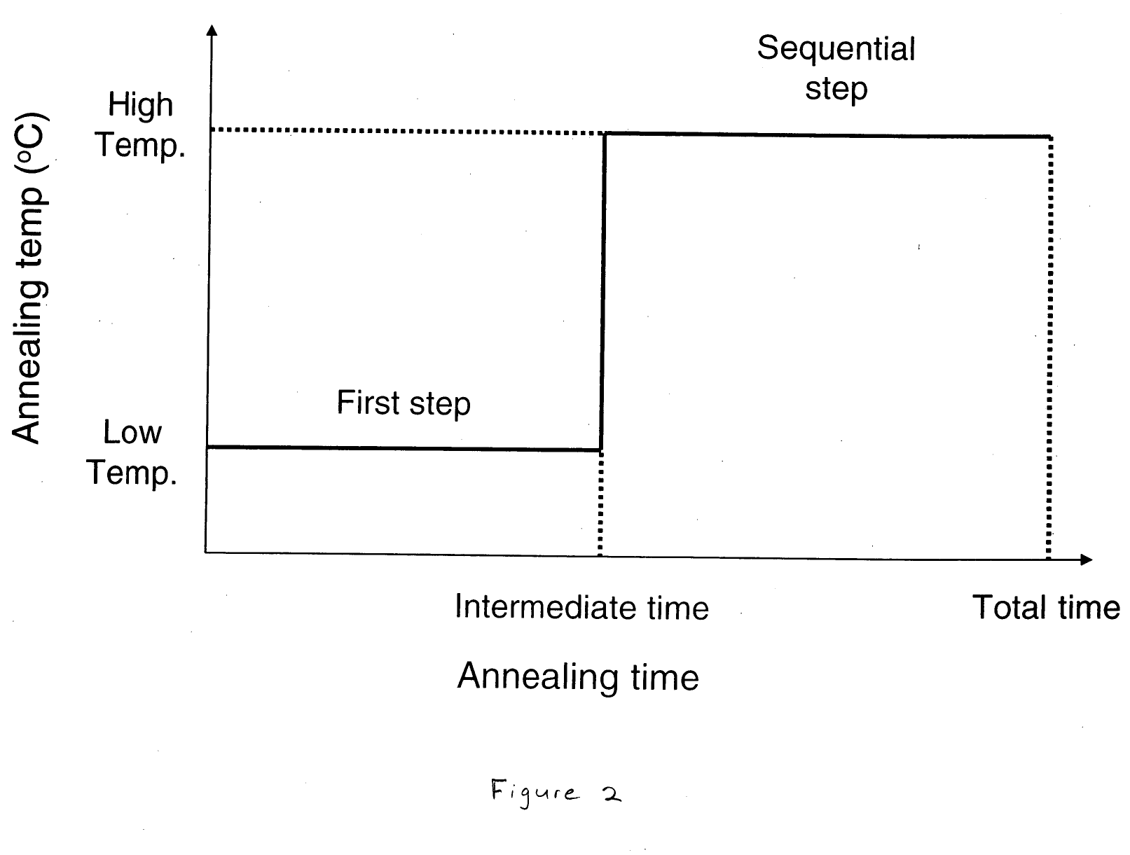

Referring to FIG. 2, a typical sequential annealing profile in accordance with an embodiment of the invention, with a low-temperature anneal, leads to the formation of a large number of Si-nc. However, if only a low temperature annealing step is performed, appropriate Si-nc sizes may not be achieved due to a lack of energy for growth. Therefore, materials annealed only at low temperature typically do not provide good light emission. On the other hand, annealing only at a high temperature, e.g., at 1200° C., may lead to the formation of large Si-nc, but the number of Si-nc may be limited due to reduced nucleation at high temperatures. In accordance with an embodiment of the invention, sequential thermal annealing enables the formation of Si-nc having an average size that is sufficiently small to utilize quantum confinement effects for better light emission. Moreover, sequential thermal annealing as described herein also enables the creation of a significantly greater number of emitting centers.

In an embodiment of the invention, a first annealing step at a first temperature is performed in a processing chamber or annealing furnace. The first temperature may range from, e.g., 300° C. to 1300° C., preferably from 400° C. to 1250° C., and most preferably from 500° C. to 1200° C. The substrate and overlying film are subsequently subjected to a second annealing step in the same processing chamber or annealing furnace. The second annealing step is performed at a second temperature that is higher than the first temperature. The second temperature may range from, e.g., 300° C. to 1300° C., preferably from 400° C. to 1250° C., and most preferably from 500° C. to 1200° C. The photoluminescence of the film after the second annealing step is greater than the photoluminescence before the first annealing step.

In an embodiment, the substrate remains in the processing chamber or annealing furnace between the first and second annealing steps. Alternatively, the substrate may be removed from the processing chamber or annealing furnace after the first step, and re-inserted therein for the second step after the temperature of the processing chamber or annealing furnace is stabilized at the second temperature.

### EXPERIMENTAL RESULTS

The effects of sequential thermal annealing steps on light emission were investigated, with the goal of increasing the density of Si-nc and to increase their emission intensity. Specifically, the role of sequential thermal annealing steps on the inducement of Si-nc nucleation and activation of efficient light emission was investigated in a controlled nitrogen atmosphere. After thermal annealing, strong near infrared (700-900 nm) light emission at room temperature under optical pumping was observed.

Room-temperature photoluminescence experiments were preformed by using a 488 nm Ar pump laser and a liquid nitrogen cooled InGaAs photomultiplier tube.

Low temperature pre-annealing treatment of reactively sputtered substoichiometric oxide (e.g., a SiOₓ matrix) films was performed to induce the formation of a large number of small Si clusters that can act as initial nucleation sites for a subsequent nucleation induced by a higher temperature treatment.

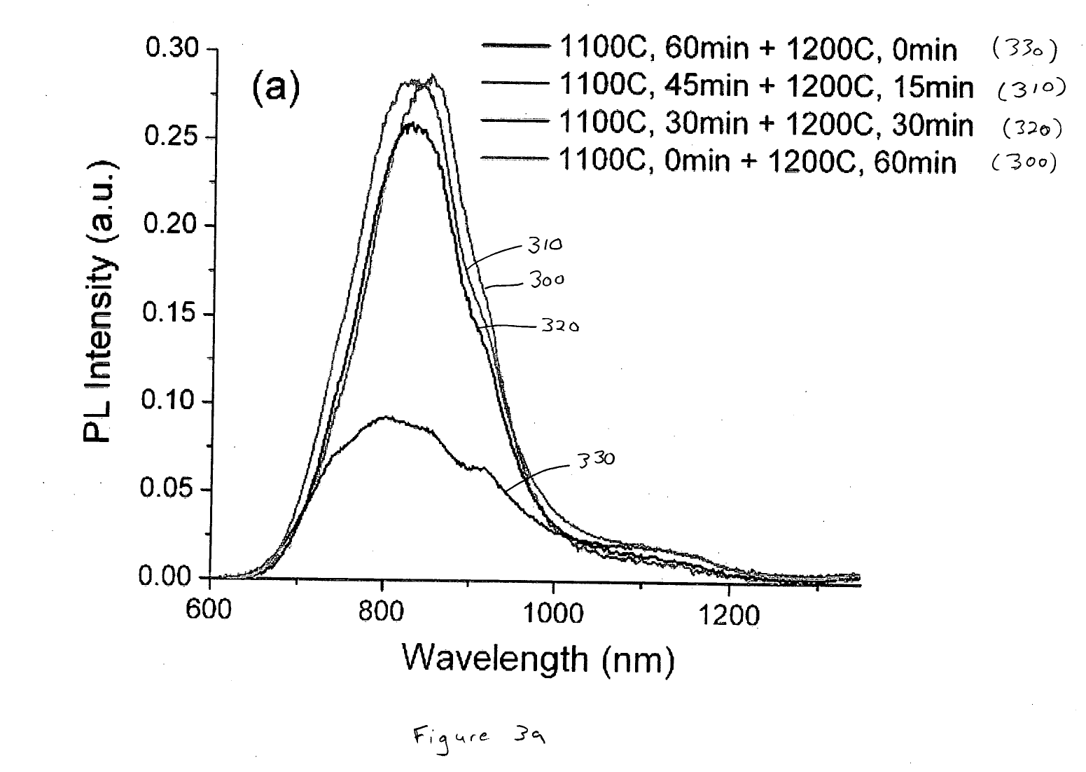

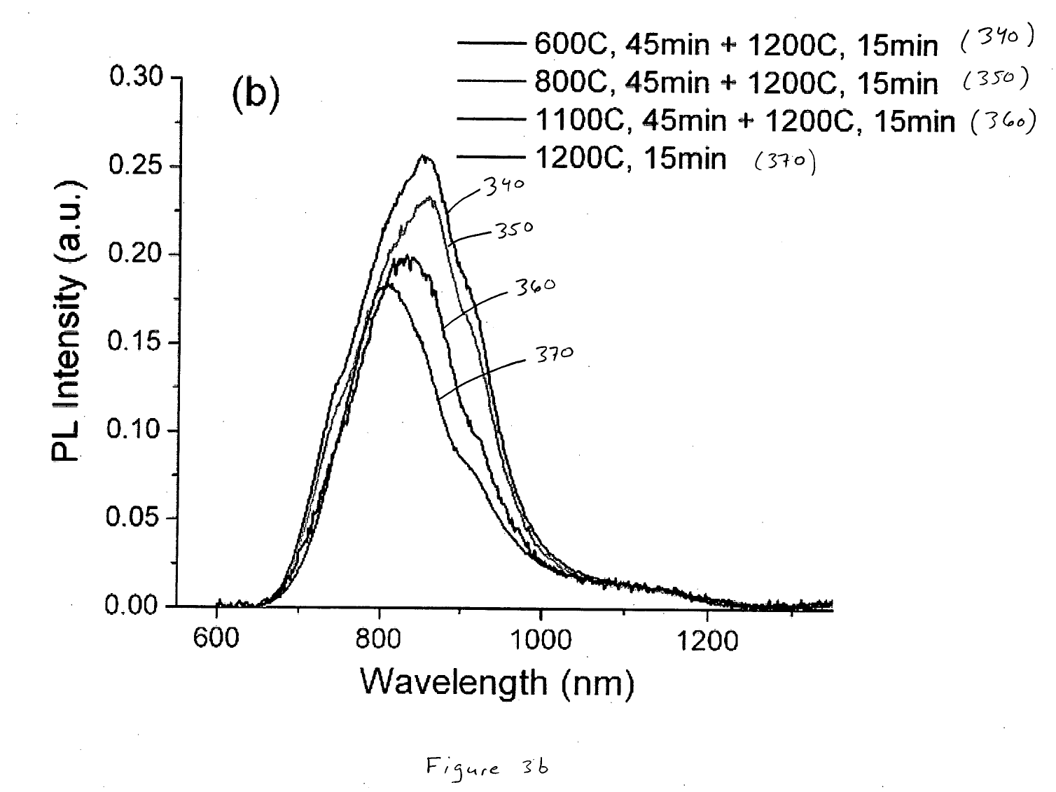

All of the experimental annealing treatments were performed in a controlled nitrogen atmosphere. Typical annealing temperatures ranged from 600° C. to 1200° C., and the total annealing time was kept fixed to 1 hour. FIG. 3(a) illustrates room-temperature photoluminescence spectra for structures subjected to a first annealing step for a duration of 15, 30, or 45 minutes at a fixed temperature of 1100° C. in an annealing furnace, and then subjected to a second annealing step at 1200° C. in the same annealing furnace for a duration selected such that the total annealing time was 1 hour (i.e., 45, 30, or 15 minutes, respectively). The substrate remained in the annealing furnace between the first and second annealing steps. In some embodiments, the substrate may be removed from a processing chamber or annealing furnace after the first annealing step, and re-inserted into the processing chamber or furnace for the second step after a temperature of the processing chamber or furnace is stabilized at the second temperature.

As shown in FIG. 3(a), the light-emission intensity is highest in samples annealed for either 1 hour at 1200° C. (curve 300), or for a shorter annealing time at the same 1200° C. temperature, but following a pre-annealing step at 1100° C. (curve 310). A similar light emission intensity appears to have been achieved at a sequential anneal of 30 minutes at 1100° C. and 30 minutes at 1200° C. (curve 320). A 1 hour anneal solely at 1100° C. yields the poorest light emission intensity (curve 330). This evidence strongly supports the idea that a pre-annealing step performed at a lower temperature can drastically influence the Si-nc nucleation process.

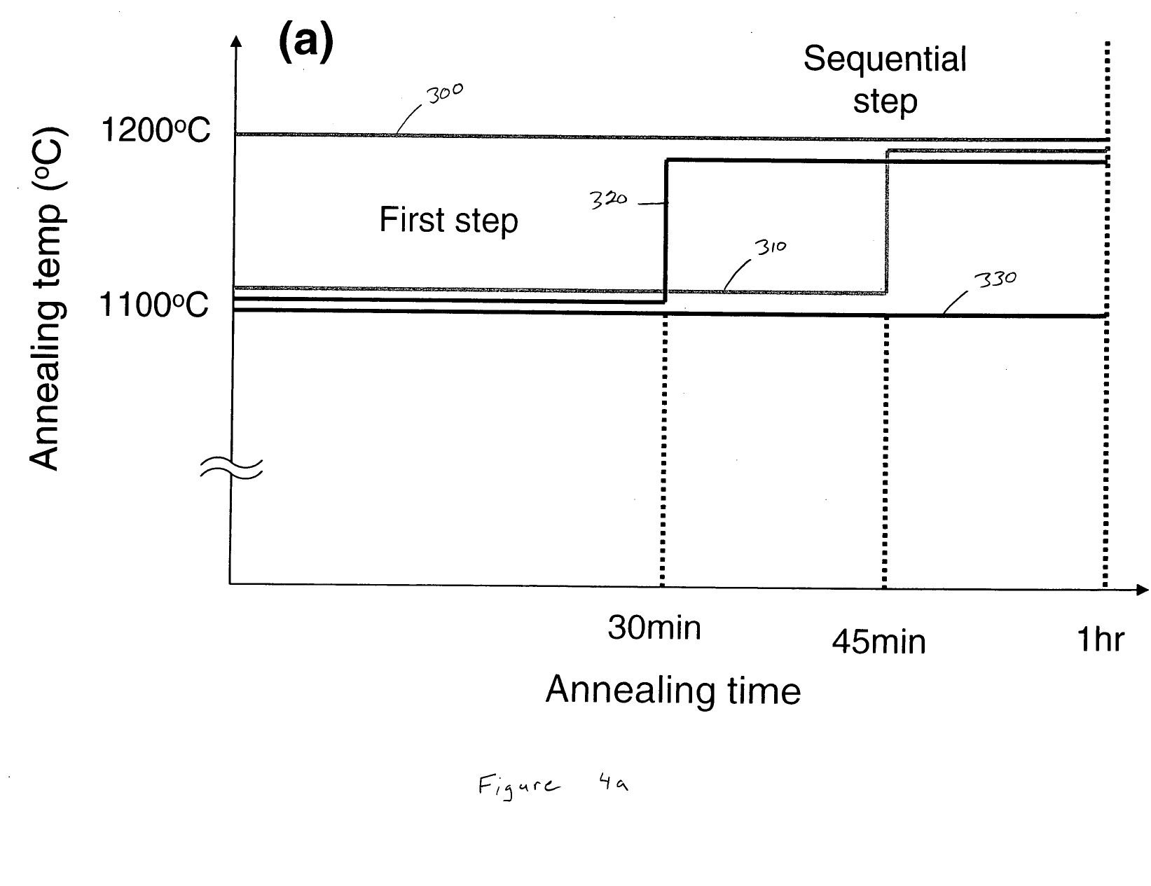

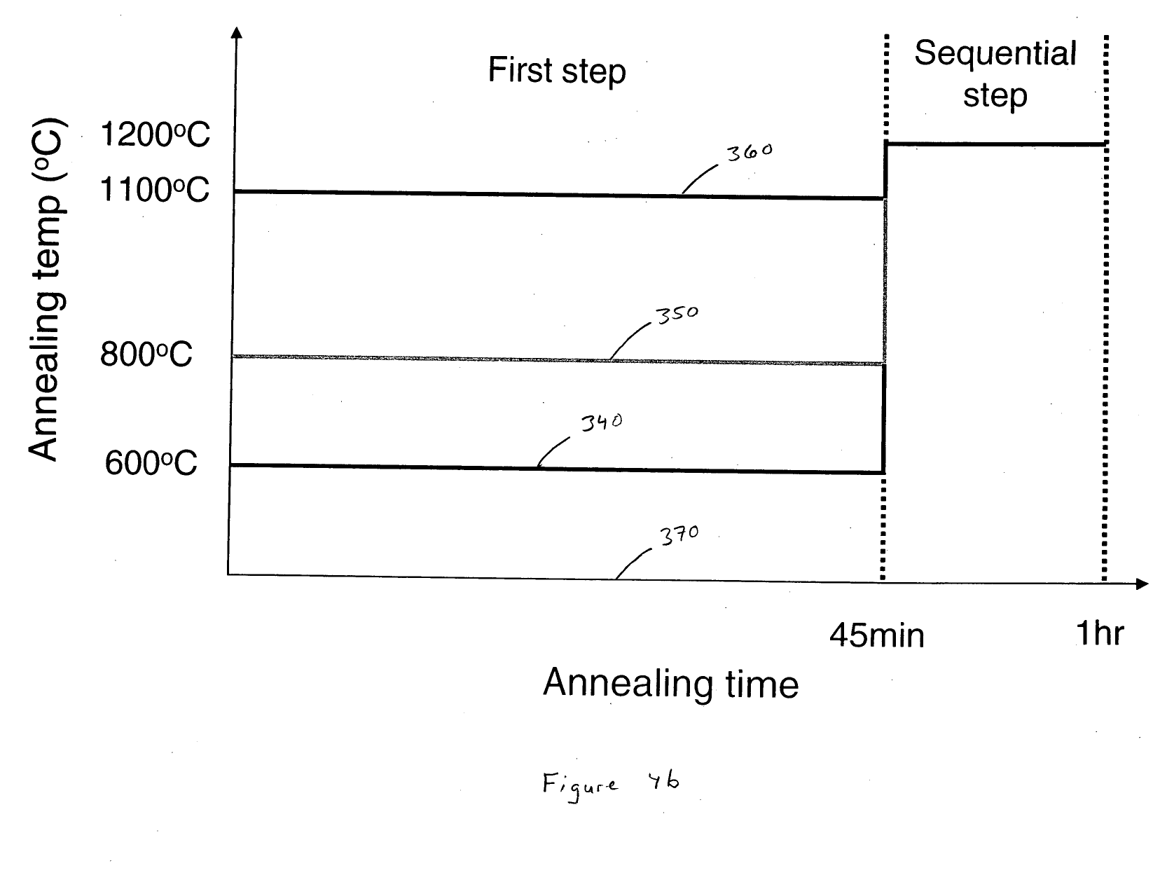

FIG. 3(b) illustrates the results of a more detailed investigation of the influence of the low temperature pre-annealing steps. Here, a pre-anneal was performed for 45 minutes at different temperatures between 600° C. and 1100° C., i.e., at 600° C. (curve 340), 800° C. (curve 350), 1100° C. (curve 360), and no pre-anneal (curve 370), and a post-anneal was performed for 15 minutes at a fixed temperature of 1200° C. The annealing temperature profiles are illustrated in FIGS. 4a and 4b. As one can see, the lower the temperature of the first anneal, the higher the final photoluminescence intensity.

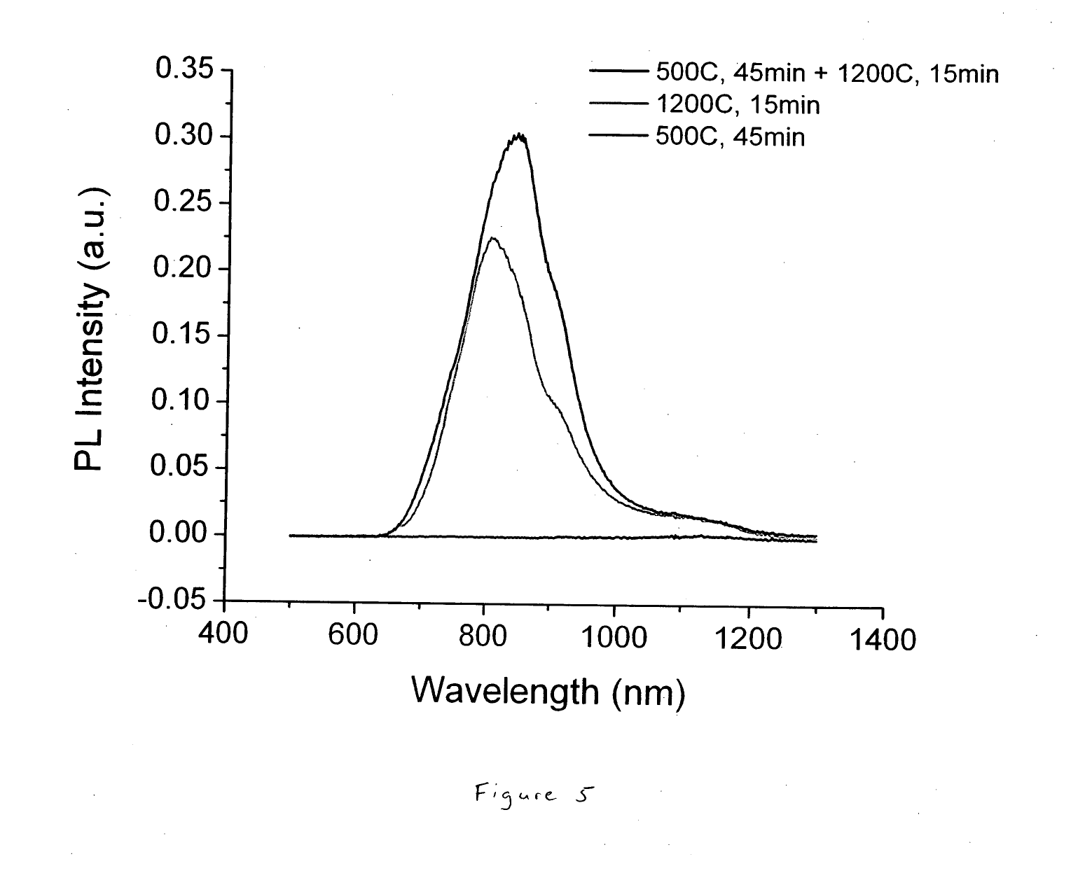

Referring to FIG. 5, the effect of sequential annealing is clearly demonstrated by enhancement of light emission from Si-nc. A comparison was made between samples (i) annealed at only at 500° C. for 45 minutes, (ii) annealed at 500° C. for 45 minutes combined with an anneal at 1200° C. for 15 minutes, and (iii) annealed only at 1200° C. for 15 minutes. Annealing at 500° C. did not have a perceivable effect on the PL intensity of a sample. Moreover, even though PL intensity greatly improved by annealing at 1200° C., the PL intensity of a sample annealed at only 1200° C. is much smaller than that of a sequentially annealed sample.

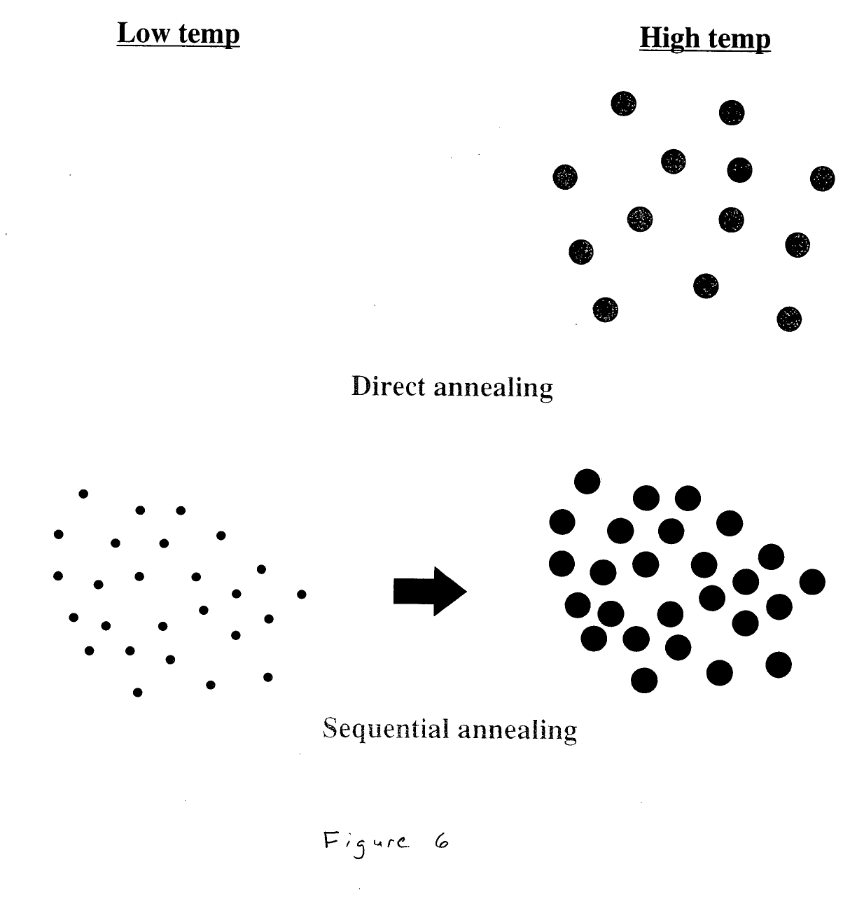

FIGS. 6a and 6b illustrate the likely basis for the improvement of light emission by sequential annealing. Without sequential annealing (see FIG. 6a), the density of light emitters in a film (e.g., Si-nc) is much smaller than that of sequentially annealed film (see FIG. 6b). Embodiments of the invention allow the enhanced nucleation of light emitters in materials such as SiO₂, Si₃N₄, Si-rich silicon oxide, Si-rich silicon nitride, and Si-rich oxynitride, and the improvement of light emission performances by direct control of the initial nucleation site density.

The invention may be embodied in other specific forms without departing from the spirit or essential characteristics thereof. The foregoing embodiments are therefore to be considered in all respects illustrative of the invention described herein. Various features and elements of the different embodiments can be used in different combinations and permutations, as will be apparent to those skilled in the art. The scope of the invention is thus indicated by the appended claims rather than by the foregoing description, and all changes which come within the meaning and range of equivalency of the claims are therefore intended to be embraced herein.

What is claimed is:

1. A method for enhancing photoluminescence, the method comprising the steps of:
providing a film over a substrate, the film including at least one of a semiconductor and a dielectric material;
performing a first annealing step at a first temperature in a processing chamber or annealing furnace; and
thereafter, performing a second annealing step at a second temperature in the processing chamber or annealing furnace,
wherein the second temperature is greater than the first temperature, and a second photoluminescence of the film after the second annealing step is greater than an initial photoluminescence of the film before the first annealing step.

2. The method of claim 1, wherein the substrate remains in the processing chamber or annealing furnace between the first and second annealing steps.

3. The method of claim 1, wherein the substrate is removed from the processing chamber or annealing furnace after the first step, and re-inserted into the processing chamber or furnace for the second step after a temperature of the processing chamber or annealing furnace is stabilized at the second temperature.

4. The method of claim 1, wherein the film comprises silicon.

5. The method of claim 4, wherein the dielectric material comprises at least one of SiO₂, Si₃N₄, Si-rich silicon oxide, Si-rich silicon nitride, and Si-rich oxynitride.

6. The method of claim 5, wherein the dielectric material comprises at least one of SiO₂ and Si-rich silicon oxide, and the first temperature is selected from a range of 300° C. to 1300° C.

7. The method of claim 6, wherein the first temperature is selected from a range of 400° C. to 1250° C.

8. The method of claim 7, wherein the first temperature is selected from the range of 500° C. to 1200° C.

9. The method of claim 5, wherein the dielectric material comprises at least one of SiO₂ and Si-rich silicon oxide and the second temperature is selected from a range of 300° C. to 1300° C.

10. The method of claim 9, wherein the second temperature is selected from a range of 400° C. to 1250° C.

11. The method of claim 10, wherein the second temperature is selected from a range of 500° C. to 1200° C.

12. The method of claim 1, wherein a thickness of the film is selected from a range of 0.1 μm to 5 μm.
